(19) United States
(12) Patent Application Publication
(10) Pub. No.: US 2024/0222129 A1
(43) Pub. Date: Jul. 4, 2024

(54) METHOD AND DEVICE FOR FILLING A REAR-SIDE CAVITY OF A SEMICONDUCTOR ASSEMBLY

(71) Applicant: Robert Bosch GmbH, Stuttgart (DE)

(72) Inventors: Christian Huber, Ludwigsburg (DE); Holger Wuest, Waldenbuch (DE); Jens Baringshaus, Sindelfingen (DE); Jonas Ott, Boeblingen (DE)

(21) Appl. No.: 18/557,468

(22) PCT Filed: Apr. 22, 2022
(86) PCT No.: PCT/EP2022/060703

§ 371 Date: Nov. 28, 2023

(30) Foreign Application Priority Data
Apr. 29, 2021 (DE) 10 2021 204 294.5

(51) Int. Cl. H01L 21/288; C23C 24/10

(52) U.S. Cl. CPC H01L 21/288; C23C 24/106

(57) ABSTRACT

A method for filling a rear-side cavity of a semiconductor assembly, the rear-side cavity having a metal layer. The method includes: dispensing a suspension with a specified drop size into the rear-side cavity of the semiconductor assembly using a drop applicator, wherein the suspension has a metal-containing powder and a liquid dispersion medium and the metal-containing powder has a particle size in the nanometer range; and heating the semiconductor assembly to a temperature of less than 500° C., whereby the metal-containing powder is sintered.

### FIELD

The present invention relates to a method and a device for filling a rear-side cavity of a semiconductor assembly.

### BACKGROUND INFORMATION

Vertical semiconductor elements in which heteroepitaxial layers of SiC or GaN are deposited on a foreign substrate require cavities on the rear side with an extension of a few millimeters for the electrical current flow. In order to ensure the stability of the semiconductor element and an electrical connection, these cavities must be filled with a metal.

A disadvantage here is that such large cavities cannot be filled cost-effectively, quickly, and selectively using conventional semiconductor processes.

An object of the present invention is to overcome these disadvantages.

### SUMMARY

A method according to an example embodiment of the present invention for filling a rear-side cavity of a semiconductor assembly, wherein the rear-side cavity has a metal layer, comprises dispensing a suspension with a specified drop size into the rear-side cavity of the semiconductor assembly by means of a drop applicator. The suspension has a metal-containing powder and a liquid dispersion medium. The metal-containing powder has a particle size in the nanometer range. In other words, it is a metal-containing nanopowder. The method comprises heating the semiconductor assembly to a temperature of less than 500° C., the metal-containing powder being sintered in the process.

An advantage here is that filling of the rear-side cavity is targeted or selective and cost-effective. The metal is sintered at a comparatively low temperature so that semiconductor elements can be produced in this way that are no longer temperature-stable at higher sintering temperatures and cannot withstand high pressures.

In a further development of the present invention, the liquid dispersion medium is vaporized between the dispensing of the suspension and the heating of the semiconductor device.

An advantage here is that the packing compactness of the powder particles of a dried suspension is higher than that of a pure metal powder, so that sintering is faster.

In one example embodiment of the present invention, the dispensing of the suspension with the specified drop size into the rear-side cavity of the semiconductor assembly with the aid of the drop applicator and the heating of the semiconductor assembly to a temperature of less than 500° C. take place simultaneously.

An advantage here is that the rear-side cavity is filled quickly.

In a further development of the present invention, gaps between the rear-side cavity and the sintered metal-containing powder are detected and the drop applicator is controlled depending on the detected gaps, wherein the suspension is dispensed into the gaps.

An advantage here is that the filling of the rear-side cavity can be controlled in situ depending on the process.

In a further embodiment of the present invention, a size of the gaps is detected and the specified drop size of the suspension is adjusted with the aid of the drop applicator depending on the size of the gaps.

An advantage here is that the gaps created by the compaction of the powder are filled in order to achieve complete filling of the cavities.

In a further development of the present invention, the metal layer of the rear-side cavity and the metal-containing powder of the suspension have the same metal.

An advantage here is that a material bond is created between the semiconductor substrate, the metal layer, and the sintered metal-containing powder.

In a further embodiment of the present invention, the specified drop size comprises a maximum of 1 μl.

An advantage here is that standard drop applicators can be used.

In a further development of the present invention, the metal-containing powder has a particle size of less than 1 μm.

An advantage here is that the sintering temperature can be lowered well below the melting point of the material used.

In a further development of the present invention, the metal-containing powder comprises copper.

An advantage here is that a very good conductivity of the filled rear-side cavity is achieved.

According to an example embodiment of the present invention, the device for filling a rear-side cavity of a semiconductor assembly, the rear-side cavity having a metal layer, comprises a drop applicator adapted to dispense a suspension with a specified drop size, the suspension comprising a metal-containing powder and a liquid dispersion medium, and a temperature device which heats the semiconductor assembly.

According to the present invention, the metal-containing powder has a particle size in the nanometer range. The temperature device sets a temperature of less than 500° C.

Further advantages will emerge from the disclosure herein.

### BRIEF DESCRIPTION OF THE DRAWINGS

The present invention is explained in the following with reference to preferred embodiments and the figures.

FIG. 1 shows a first exemplary embodiment of a method according to the present invention for filling a rear-side cavity of a semiconductor assembly.

FIG. 2 shows a second exemplary embodiment of the method according to the present invention for filling a rear-side cavity of a semiconductor assembly.

FIG. 3A shows a process result of the simultaneously performed process steps 210 and 230 from FIG. 2.

FIG. 3B shows a process result after carrying out the process step 260 of FIG. 2.

FIG. 4 shows a device according to an example embodiment of the present invention for filling a rear-side cavity of a semiconductor assembly.

### DETAILED DESCRIPTION OF EXAMPLE EMBODIMENTS

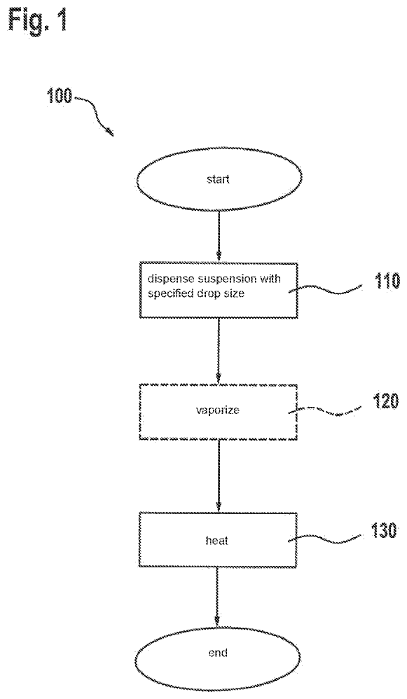

FIG. 1 shows a first exemplary embodiment of a method 100 according to the present invention for filling a rear-side cavity of a semiconductor assembly. The method 100 starts with step 110, in which a suspension with a specified drop size is dispensed into the rear-side cavity of the semiconductor assembly using a drop applicator. The specified drop size has a volume of between several nl and 1 μl. The suspension comprises a metal-containing powder with a particle size in the nanometer range and a liquid dispersion medium. The solids content of the suspension comprises at least 20% by volume, preferably more than 40% by volume. By mixing in chemical additives, the solids content of the suspension can increase to 50-70% by volume. One such chemical additive is trioxadecanoic acid, for example. The particle size of the metal-containing powder is less than 1 μm, in particular 500 nm, preferably 300 nm. The liquid dispersion medium can be alcohol or water. Depending on the selected liquid dispersion medium, the liquid dispersion medium is vaporized in an optional subsequent step 120 with the aid of an external heat source, e.g., an infrared lamp or a xenon lamp. In a subsequent step 130, the semiconductor assembly is heated to a temperature of less than 500° C. with the aid of a temperature device. The temperature is preferably between 300° C. and 500° C. This causes the metal-containing powder to be sintered and compacted. Compaction takes place up to a specified compactness or completely. Due to the nanometer-sized metal particles, the sintering temperature is considerably lower than the usual sintering temperature of larger particles of the same metal. In other words, only the low sintering temperature is required for sintering the metal-containing nanopowder. This means that no increased pressures are required to compact the metal-containing nanopowder.

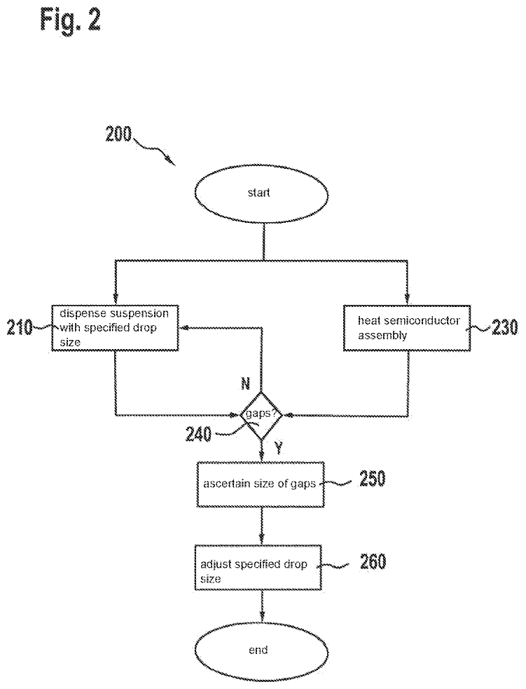

FIG. 2 shows a second exemplary embodiment of the method 200 according to the present invention for filling a rear-side cavity of a semiconductor assembly. The method starts with steps 210 and 230, wherein steps 210 and 230 are carried out simultaneously. That is, in step 230, the semiconductor assembly is heated to a specified temperature using a temperature device, while in step 210, a suspension is dispensed with a specified drop size into the rear-side cavity of the semiconductor assembly using a drop applicator, wherein the suspension comprises a metal-containing nanopowder and a liquid dispersion medium. The liquid dispersion medium vaporizes immediately and the metal-containing nanopowder is continuously sintered and compacted, wherein suspension is constantly dispensed or added. In order to achieve the greatest possible compaction of the nanopowder, it is possible to suspend the continuous dispensing of the suspension into the rear-side cavity for a specified time, while the temperature device maintains the low sintering temperature. The drop applicator can thus temporarily fill a different rear-side cavity of the semiconductor assembly. In a subsequent step 240, gaps between the rear-side cavity and the already sintered nanopowder, which can occur due to the compaction of the nanopowder, are detected. If gaps have been detected, the size of the gaps is ascertained in a subsequent step 250. In a subsequent step 260, the specified drop size of the suspension is adjusted as a function of the size of the gaps. If no gaps are detected between the rear-side cavity and the already sintered nanopowder, the method is continued with step 210.

To control the porosity of the filled rear-side cavity, the heating of the semiconductor assembly can be interrupted or the semiconductor assembly can be moved to a cooler area of the production system.

By filling the rear-side cavity with the suspension, a very defined surface can also be created at the upper edge of the rear-side cavity, so that a planar finish is achieved, allowing subsequent process steps such as assembly and joining technology, as well as soldering processes, to be carried out easily.

In both in the first exemplary embodiment and in the second exemplary embodiment, the rear-side cavity can have a metal layer. This creates a material bond between the metal layer and the sintered metal-containing nanopowder. In order to prevent metal atoms of the sintered metal-containing powder from diffusing into the semiconductor substrate, thin layers can be integrated between the metal layer and the semiconductor substrate as diffusion barriers. Diffusion barriers between copper and silicon can be thin layers based on tantalum, for example.

In both exemplary embodiments, the metal-containing powder is preferably copper.

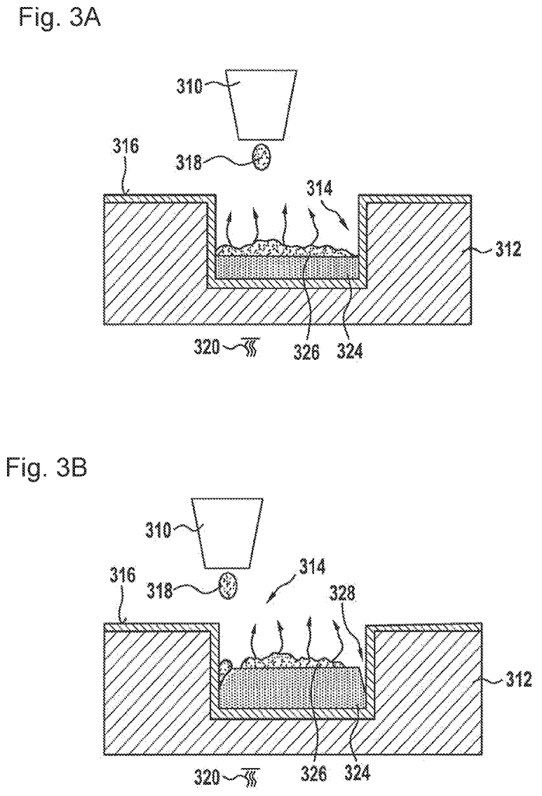

FIG. 3A shows the process result of the simultaneously performed process steps 210 and 230 from FIG. 2. FIG. 3A shows a drop applicator 310, a semiconductor substrate 312 with a rear-side cavity 314, wherein the rear-side cavity 314 comprises a metal layer 316. The drop applicator 310 dispenses a suspension containing a metal-containing nanopowder into the rear-side cavity, and a temperature device 320 simultaneously heats the semiconductor assembly to a temperature below 500° C. Already sintered metal-containing nanopowder 324 and non-sintered metal-containing nanopowder 326 are shown inside the rear-side cavity.

FIG. 3B shows the process result after carrying out the process step 260 in FIG. 2. The same reference signs in FIG. 3B describe the same features as in FIG. 3A. Gaps 328 are shown within the rear-side cavity 314 between the rear-side cavity 314 and the already sintered metal-containing nanopowder 324.

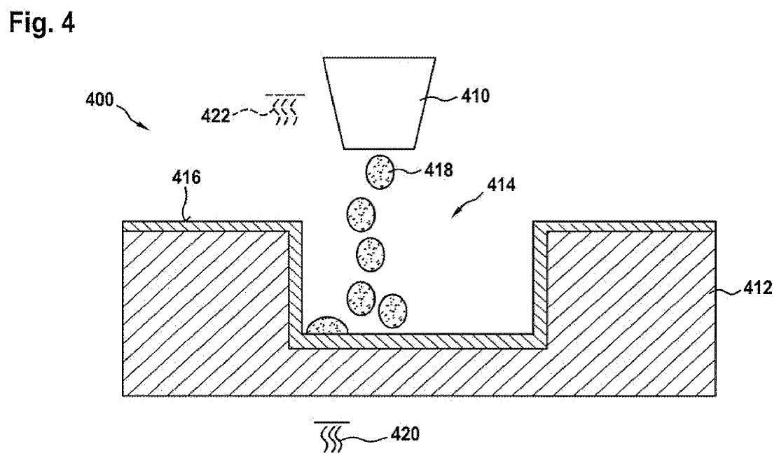

FIG. 4 shows a device 400 according to the present invention for filling a rear-side cavity 414 of a semiconductor assembly. The device 400 comprises a drop applicator 410 and a temperature device 420. The drop applicator 410 is designed to dispense a suspension 418, which comprises metal-containing nanopowder and a liquid dispersion medium, into a workpiece to be filled. Optionally, the device 400 has a heat source 422 which is set up to vaporize the liquid dispersion medium. A rear-side cavity 414 of a semiconductor assembly is shown here as an example. The rear-side cavity 414 extends into a semiconductor substrate 412 and has a metal layer 416. It is noted that the rear-side cavity 414, the semiconductor substrate 412, and the metal layer 416 are not part of the device 400.

The device 400 is used in wafer semiconductor processes and other metallization processes with nanoscale or microscale dimensions.

1-10. (canceled)

11. A method of filling a rear-side cavity of a semiconductor assembly, the rear-side cavity having a metal layer, the method comprising the following steps:
dispensing a suspension with a specified drop size into the rear-side cavity of the semiconductor assembly using a drop applicator, the suspension including a metal-containing powder and a liquid dispersion medium, the metal-containing powder having a particle size in a nanometer range; and
heating the semiconductor assembly to a temperature of less than 500° C., wherein the metal-containing powder is sintered.

12. The method according to claim 11, wherein a vaporization of the liquid dispersion medium takes place between the dispensing of the suspension and the heating of the semiconductor device.

13. The method according to claim 11, wherein the dispensing of the suspension and the heating of the semiconductor assembly take place simultaneously.

14. The method according to claim 13, wherein gaps between the rear-side cavity and the sintered metal-containing powder are detected and the drop applicator is controlled as a function of the detected gaps, the suspension being dispensed into the gaps.

15. The method according to claim 14, wherein a size of the gaps is detected and the specified drop size of the suspension is adjusted as a function of the size of the gaps.

16. The method according to claim 11, wherein the metal layer of the rear-side cavity and the metal-containing powder of the suspension includes the same metal.

17. The method according to claim 11, wherein the specified drop size includes a maximum of 1 μl.

18. The method according to claim 11, wherein the metal-containing powder has a particle size of less than 1 μm.

19. The method according to claim 11, wherein the metal-containing powder includes copper.

20. A device for filling a rear-side cavity of a semiconductor assembly, the rear-side cavity having a metal layer, the device comprising:
a drop applicator adapted to dispense a suspension with a specified drop size, the suspension including a metal-containing powder and a liquid dispersion medium; and
a temperature device configured to heat the semiconductor assembly;
wherein the metal-containing powder has a particle size in a nanometer range, and the temperature device sets a temperature of less than 500° C.
